(19) United States
(12) Patent Application Publication
(10) Pub. No.: US 2016/0201195 A1
(43) Pub. Date: Jul. 14, 2016

(54) DEPOSITING APPARATUS

(71) Applicant: Samsung Display Co., Ltd., Yongin-city (KR)

(72) Inventors: Byung Chul LEE, Seoul (KR); Gan Young PARK, Cheongju-si (KR); Chang Sik LEE, Hwaseong-si (KR); Seong Ho JEONG, Suwon-si (KR); Hyun CHOI, Anyang-si (KR)

(21) Appl. No.: 14/739,149

(22) Filed: Jun. 15, 2015

(30) Foreign Application Priority Data
Jan. 14, 2015 (KR) 10-2015-0007027

(51) Int. Cl. C23C 16/455

(52) U.S. Cl. CPC C23C 16/45563

(57) ABSTRACT

A deposition apparatus includes: a deposition source disposed facing a substrate and configured to accommodate a deposition material; and a plurality of injection nozzles arranged from one side of the deposition source along a first direction, the plurality of injection nozzles configured to inject the deposition material onto the substrate, each injection nozzle including: a first injection part including a first injection passage which has one end connected to the deposition source and extends along a second direction between the deposition source and the substrate, and a second injection part including a second injection passage which has walls extending from the other end of the first injection passage in a direction inclined at a predetermined inclined angle with respect to the second direction, wherein the first direction is a length direction of the deposition source and the second direction is a height direction of the deposition source.

### CROSS REFERENCE TO RELATED APPLICATION

This application claims priority from and the benefit of Korean Patent Application No. 10-2015-0007027, filed on Jan. 14, 2015, which is hereby incorporated by reference for all purposes as if fully set forth herein.

### BACKGROUND

1. Field

Exemplary embodiments relate to a depositing apparatus.

2. Discussion of the Background

An organic material, metal used as an electrode, etc., in display devices such as an organic light emitting diode display and a liquid crystal display are generally formed by a vacuum deposition method for depositing the corresponding material under the vacuum conditions to form a thin film on a flat panel. The vacuum deposition method disposes a substrate inside a vacuum chamber, disposes a mask having a pattern of the thin film on the substrate, and then, evaporates and/or sublimates a deposition material such as an organic material using a deposition source to deposit the evaporated or sublimated deposition material onto the substrate.

Since the deposition material radiated from the evaporation source may be injected at various radiation angles, a shadow phenomenon may occur wherein the organic material may be non-uniformly permeated between the mask and the substrate depending on an angle at which the deposition material is injected to reach the substrate.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a depositing apparatus having advantages of increasing deposition uniformity and deposition efficiency by improving a shadow phenomenon of a deposition material which is incident on a substrate.

Additional aspects will be set forth in the detailed description which follows, and, in part, will be apparent from the disclosure, or may be learned by practice of the inventive concept.

According to exemplary embodiments, a depositing apparatus includes: a deposition source disposed facing a substrate and configured to accommodate a deposition material; and a plurality of injection nozzles arranged from one side of the deposition source along a first direction, the plurality of injection nozzles configured to inject the deposition material onto the substrate, each injection nozzle including: a first injection part including a first injection passage which has one end connected to the deposition source and extends along a second direction between the deposition source and the substrate, and a second injection part including a second injection passage which has walls extending from the other end of the first injection passage in a direction inclined at a predetermined inclined angle with respect to the second direction, wherein the first direction is a length direction of the deposition source and the second direction is a height direction of the deposition source.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a perspective view of a depositing apparatus according to one or more exemplary embodiments.

FIG. 2 is a schematic diagram illustrating a correlation between an angle of a deposition material incident onto a substrate and an injection nozzle, according to one or more exemplary embodiments.

FIG. 3 is a cross-sectional view illustrating one of a plurality of injection nozzles according to one or more exemplary embodiments.

FIGS. 4 and 5 are cross-sectional views illustrating one of the plurality of injection nozzles according to the exemplary embodiments.

FIG. 6 is a schematic diagram illustrating an exemplary arrangement of the injection nozzles in a deposition region according to the exemplary embodiments.

FIG. 7 is a graph illustrating a change in a film thickness depending on an inclined angle of a second injection passage, according to the exemplary embodiments.

FIG. 8 is a graph illustrating the change in the film thickness depending on a length ratio of the injection nozzle, according to the exemplary embodiments.

FIG. 9 is a graph illustrating the change in the film thickness depending on a shape of the injection nozzle, according to the exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

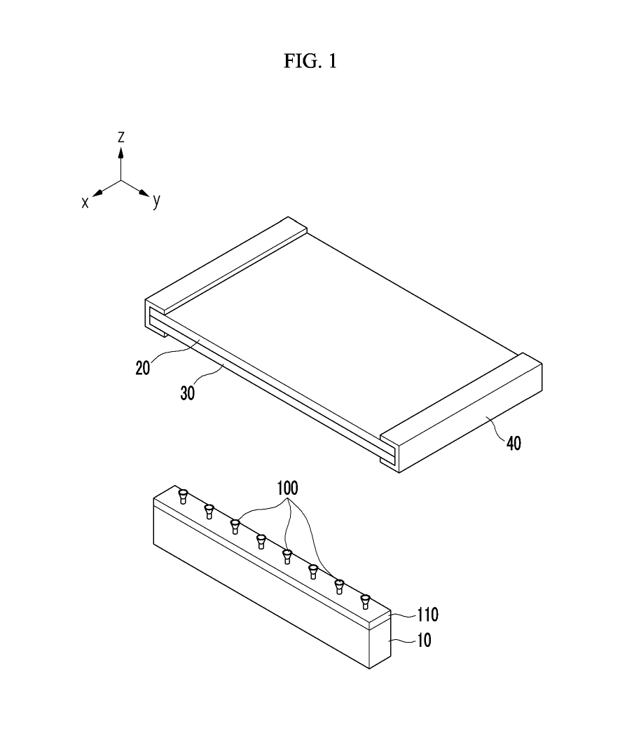

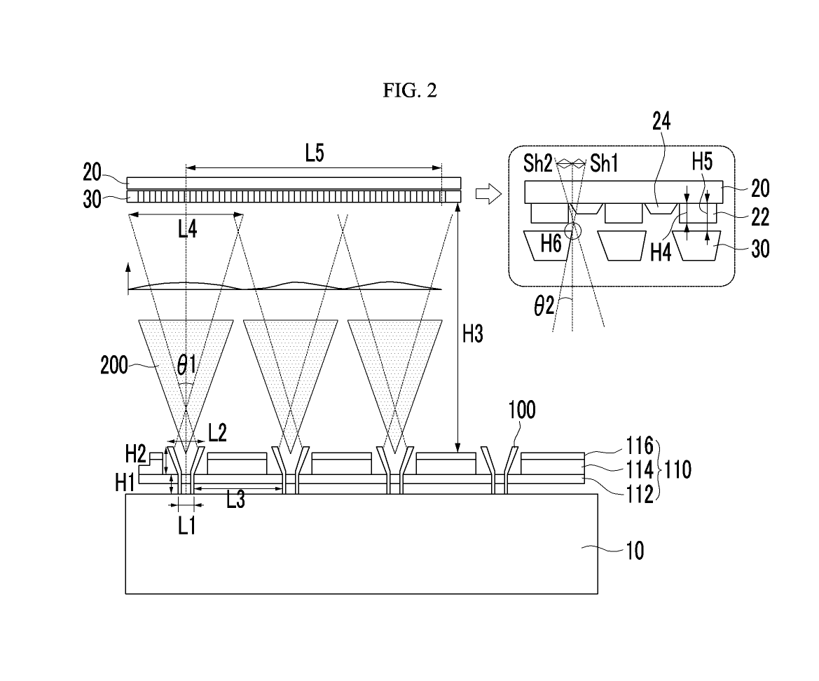

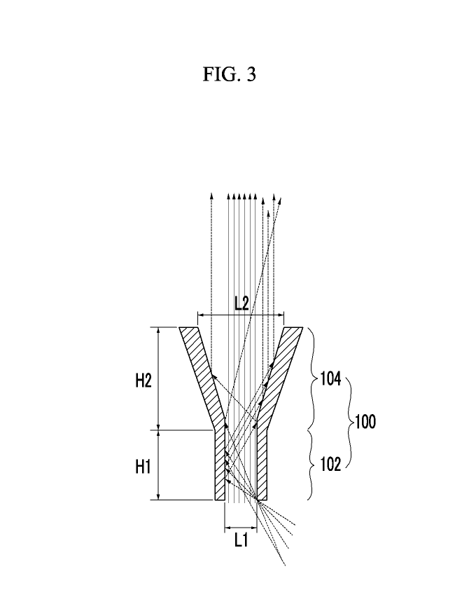

FIG. 1 is a perspective view of a depositing apparatus according to one or more exemplary embodiments, and FIG. 2 is a schematic diagram illustrating a correlation between an angle of a deposition material incident onto a substrate and a plurality of injection nozzles 100, according to one or more exemplary embodiments. FIG. 3 is a cross-sectional view illustrating the plurality of injection nozzles according to an exemplary embodiment.

Referring to FIGS. 1, 2, and 3, a depositing apparatus according to one or more exemplary embodiments may include a deposition source 10 and the plurality of injection nozzles 100, and each of the plurality of injection nozzles 100 may include a first injection part 102 and a second injection part 104. Further, the depositing apparatus may also include a nozzle protecting part 110 which is coupled between a deposition source 10 and a plurality of injection nozzles 100 to protect the plurality of injection nozzles 100. The nozzle protecting part 110 may include a heater 112 which is coupled around a first injection part 102 of the plurality of injection nozzles 100 to supply heat to the plurality of injection nozzles 100, a nozzle cover 114 disposed on the heater 112 and coupled around a second injection part 104 of the plurality of injection nozzles 100 to protect the injection nozzle 100, and a heat insulation coating layer 116 disposed on a surface of the nozzle cover 114 facing a substrate 20 to insulate the heat. The heat insulation coating layer 116 may include an insulating ceramic nano composite and the like. The heat insulating layer 116 may have a thickness according to a temperature at which heat insulation is required. For example, the heating insulating layer 116 may have about 1 mm to about 2 mm for a temperature of 400° C., which is a temperature at which heat insulation is required for organic material deposition.

The depositing apparatus according to the exemplary embodiments may be disposed within a vacuum chamber (not illustrated) which may be configured to maintain a predetermined degree of vacuum. As the vacuum chamber in which the depositing apparatus is disposed is configured to maintain the predetermined degree of vacuum, the deposition material 200 injected from the injection nozzle 100 may be injected straight. The deposition material 200 may be formed of an organic material which may form an organic emission layer, such as a sub-pixel configured to represent red (R), green (G), and blue (B) color in the display device. The vacuum chamber may have various shapes depending on a shape of the substrate 20 to be treated.

The deposition source 10 is disposed facing the substrate 20 and includes a crucible (not illustrated) which is configured to accommodated the deposition material 200 for forming a thin film on the substrate 20. The deposition source 10 may be configured to discharge and deposit the deposition material 200 onto the substrate, and the deposition source 10 may be configured to store the deposition material 200 such as an organic material in an internal space. The deposition source 10 may extend in a first direction (y-axis direction), which corresponds to a length direction of the substrate 20. The substrate 20 may be affixed to a substrate fixing part 40, together with a mask 30. The mask 30 is configured to form a pattern of an organic film on the substrate 20, and may include an opening. The organic material may be deposited on the substrate 20 through the opening of the mask 30. The deposition process may be performed while moving the deposition source 10 and the substrate 20 relative to each other.

The vacuum chamber, the deposition source 10, the nozzle protecting part 110, the mask 30, the substrate 20, and the like which are described above, may include components which are typically used in the depositing apparatus of comparative art, and therefore a detailed description thereof will be omitted.

The plurality of injection nozzles 100 are arranged in a first direction (y-axis direction), which corresponds to a length direction of the deposition source 10, and configured to inject the deposition material 200 to the substrate 20. The injection nozzle 100 may be formed in a hollow tube form shape through which the deposition material 200 is injected. Further, the injection nozzle 100 may be connected to an inner space of the deposition source 10, and may be configured to inject the deposition material 200 evaporated or sublimated from the inner space to the substrate 20. The deposition material 200 may be injected from the injection nozzle 100 under the vacuum, so the deposition material 200 may lose directionality and may be spread in all directions around an outlet of the injection nozzle 100. A shape and an angle of the injection nozzle 100 may provide a factor for increasing deposition uniformity and deposition efficiency of the deposition material 200. Therefore, a shape and an angle of the second injection part 104 (or an upper portion) of the injection nozzle 100 and a shape and an angle of the first injection part 102 (a lower portion) of the injection nozzle 100 may be different from each other. For example, the lower portion of the injection nozzle 100 may be formed in a straight shape and the upper portion of the injection nozzle 100 may be formed in an inclined shape, and thus may be formed to be larger than the lower portion of the injection nozzle 100. By forming the lower region of the injection nozzle 100 in a straight shape and an upper region of the injection nozzle 100 larger in the inclined shape, an injection passage of the deposition material 200 may be stably maintained through the lower region of the injection nozzle 100 and the upper region of the injection nozzle 100. Further, the deposition uniformity and the deposition efficiency may be increased by improving the straight directionality of the deposition material 200. Therefore, a fine metal mask (FMM), such as mask 30 used for manufacturing a high resolution panel, may have an increased hillock margin, and thus, manufacturing the mask 30 used for manufacturing the high resolution panel may be simplified. Furthermore, as the directionality of the deposition material 200 may be improved, the shadow phenomenon may be reduced, and as a result, productivity may be increased.

The first injection part 102 may have a first injection passage, of which one end is connected to the deposition source 10 and extends straight between the deposition source 10 and the substrate 20 along a second direction, which is a height direction of the deposition source 10. A second direction (z-axis direction) represents a direction orthogonal to the first direction (y-axis direction). The first injection passage is formed in a straight tube shape along the second direction, and thus, diameters of an inlet of the first injection passage and an outlet of the first injection passage may be substantially equal to each other.

The second injection part 104 has a second injection passage, which extends along the second direction from the other end of the first injection passage, and is conical with walls inclined at a predetermined angle. Based on the second direction, a length of the second injection passage may be formed to be longer than a length of the first injection passage. Based on the first direction, a diameter of the outlet of the second injection passage may be substantially larger than that of the outlet of the first injection passage. The injection nozzle may be formed as frusto-conical tube which expands out from the inlet of the second injection passage toward the outlet of the second injection passage. An inclined angle θ1 of the second injection passage may be set to be from 90° to 140°

The injection nozzle 100 may meet the following condition (L1/H1)≧(L2/H2) based on the first direction (y-axis direction) and the second direction (z-axis direction). Here, L1 represents a diameter of the outlet of the first injection passage in the first direction, L2 represents the diameter of the outlet in the second injection passage in the first direction, H1 represents the length of the first injection passage in the second direction, and H2 represents the length of the second injection passage in the second direction.

The injection nozzle 100 may include the first injection part 102 which extends vertically and the second part 104 which extends inclined, coupled with each other. The first injection part 102 primarily affects the straight directionality of the deposition material 200. Further, the second injection part 104 coupled with the vertical type first injection part 102 is configured to correct the directionality of particles which are diffuse reflected at the outlet of the first injection part 102.

The injection nozzle 100 may also be set to meet other conditions. For example, L1, H1, L2, and H2 may be set to meet the following condition: (H1+H2)>n*L1, L2>n*L1. Here, n may be a constant which is greater than or equal to 2. Here, the greater the value of n, the larger the ratio of a vertical component in a main flux of the deposition material 200. Furthermore, an inner surface of the first injection passage and an inner surface of the second injection passage may be processed to have different surface roughness. For example, the inner surface of the first injection passage may be roughly processed to have surface roughness greater than that of the inner surface of the second injection passage. That is, the straightness of the deposition material 200 may be corrected by making the surface roughness of the inner surface of the inner surface of the injection nozzle 100 different in the first injection part 102 and the second injection part 104 by controlling a processed degree of the surface roughness of the corresponding inner surface of the injection nozzle 100. Here, the surface roughness represents a degree that the surface is rough and smooth. For example, the inner surface of the first injection part 102 may be roughly processed (to have a surface roughness equal to or greater than 0.5 μm) and the inner surface of the second injection part 104 may be smoothly processed (to have a surface roughness equal to or less than 0.2 μm). The greater the surface roughness of the first injection part 102 and the lower the surface roughness of the second injection part 104, the sharper the resolution of the thickness of the deposited deposition material 200 may be. Therefore, the injected deposition material 200 may have improved directionality by using the change of directionality of deposition material 200 from the diffused reflection at the inner surface of the first injection part 102 and the inner surface of the second injection part 104, respectively, by respectively controlling the surface roughness of the inner surface of the first injection part 102 and the inner surface of the second injection part 104.

The injection nozzle 100 may have different conditions to reduce the shadow phenomenon in the organic material 24 deposited onto the substrate 20. Referring to FIG. 2, the shadow may be divided into an inner shadow Sh1 and an outer shadow Sh2. The inner shadow Sh1 may meet the following condition (H6*H5*L1*θ1)/(H3*θ2). In the above Equation, H6 may represent a hill height of the mask 30 having a value in a range from 0.1 μm to 5 μm, H5 may represent distance between the substrate 20 and the mask 30 having a value in a range from 2 μm to 100 μm, L1 may represent the diameter of the outlet of the first injection passage in the first direction having a value in a range from 0.5 mm to 30 mm as, H3 may represent a distance between the mask 30 and the nozzle in a range from 200 mm to 800 mm, and θ1 may represent an inclined angle of the second injection passage in Knudsen number (Kn). For example, the inclined angle θ1 of the second injection passage may have a value from 1 Kn to 10 Kn. Further, θ2 may represent the inclined angle of the mask 30 having a value in a range of 30° to 70°.

To improve the inner shadow Sh1 according to the above condition, a height H4 of a substrate pixel define layer (substrate PDL) 22 and the distance H5 between the substrate 20 and the mask 30 may be decreased, the hillock height H6 of the mask 30 may be decreased, and the inclined angle θ2 of the mask 30 may be increased. The inner shadow Sh1 may be further reduced by reducing the inclined angle θ1 of the second injection passage.

The outer shadow Sh2 may meet the following condition (H5*θ1*L5)/H3. In the above Equation, L5 represents a distance between the nozzle and a tip of the nozzle and H3 represents a distance between the substrate 20 and the nozzle. To improve the outer shadow Sh2 under the condition, the height H4 of the pixel define layer (substrate PDL) of the substrate 20 and the interval H5 between the substrate 20 and the mask 30 may be reduced, the distance L5 between nozzle and the tip of the nozzle may be reduced, and the distance H3 between the substrate 20 and the nozzle may be increased. The outer shadow Sh2 may be further reduced by reducing the inclined angle θ1 of the second injection passage.

As described above, the plurality of injection nozzles 100 may be arranged in a row along the deposition source 10 extending in the first direction. Further, the upper and lower portions of each of the plurality of injection nozzles 100 may have different shapes. In this case, a nozzle length and a nozzle height of the lower portion of the injection nozzle 100 may be formed to be smaller than a nozzle length and a nozzle height of the upper portion of the injection nozzle 100. For example, the lower portion of the injection nozzle 100 may be formed in the vertical type extending in the second direction and the upper portion of the injection nozzle 100 may be formed in the inclined type extending inclined toward both sides from a center line of the lower portion of the injection nozzle 100. That is, the lower portion of the injection nozzle 100 is formed to be narrow and vertical and the upper portion of the injection nozzle 100 may be formed to be relatively wider and inclined. The upper portion of the injection nozzle 100 may be formed in variously shape as long as it has an inclined shape relatively wider than the shape of the lower portion of the injection nozzle 100. For example, the shape of the upper portion of the injection nozzle 100 may be continuously formed at different angles along the inclined direction and configured to differently control an injected quantity of the deposition material 200 with respect to the deposition. The exemplary embodiments are not limited to the illustrated shape of the injection nozzles, and therefore, the injection nozzle 100 may have various shapes as long as the shape of the injection nozzle 100 is a Y shape having a lower vertical portion of the injection nozzle 100 and an upper portion inclined type.

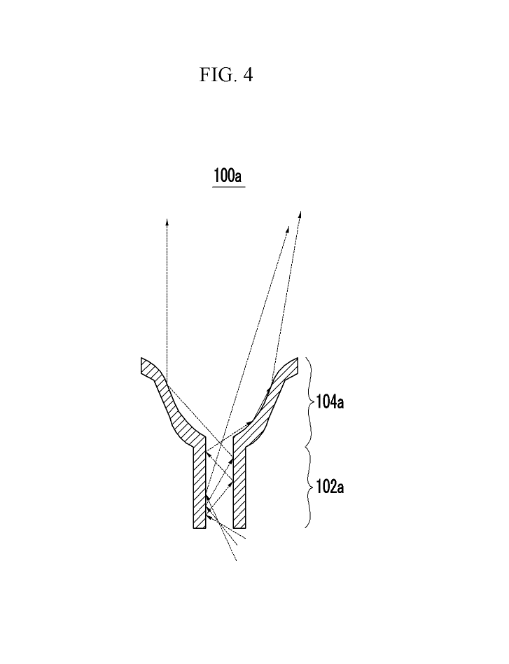

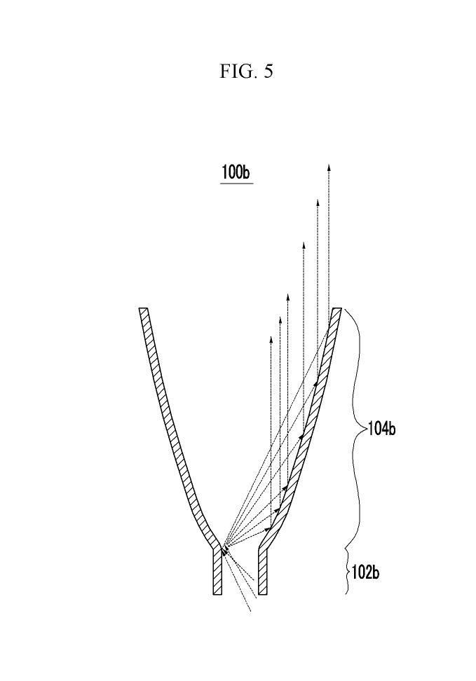

FIGS. 4 and 5 are cross-sectional views illustrating the injection nozzle according to the exemplary embodiments. FIG. 4 illustrates an injection nozzle 100a in a trumpet shape and FIG. 5 illustrates an injection nozzle 100b in a bell shape. Referring to FIG. 4, the second injection passage may be formed with walls inclined outward at the outlet of the second injection passage. Referring to FIG. 5, the diameter L2 of the outlet of the second injection passage may be formed larger than the diameter L1 of the outlet of the first injection passage. For example, the diameter L2 of the outlet of the second injection passage may be formed three times the diameter L1 of the outlet of the first injection passage. As illustrated in FIGS. 4 and 5, the injection nozzles 100a and 100b may be formed to have various shapes. The injection nozzles 100a and 100b may be formed to different shapes as long as they meet a condition that a defused reflection angle makes the directionality of the deposition materials 200 injected from the injection nozzles 100a and 1001b at the outlets of the injection nozzles 100a and 100b.

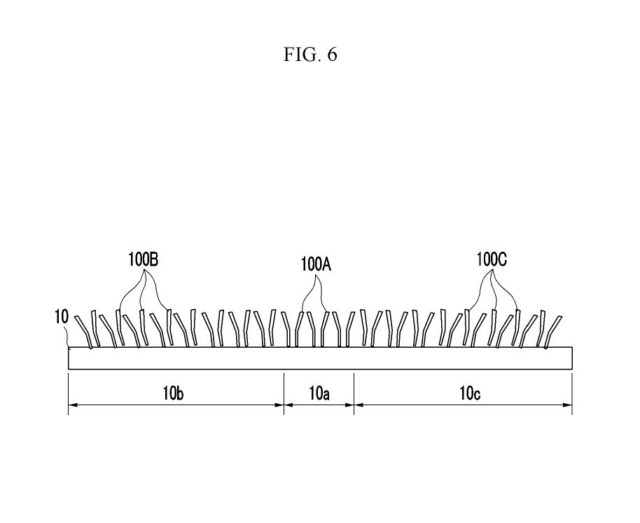

FIG. 6 is a schematic diagram illustrating an exemplary arrangement of the injection nozzles in a deposition region according to the exemplary embodiments. Referring to FIG. 6, the deposition source 10 may include a central region 10a, and a left region 10b and a right region 10c disposed at each sides of the central region 10a, in which the injection nozzles 100A, 100B, and 100C are respectively arranged with respect to the first direction. According to exemplary embodiments, the injection nozzles 100A, 100B, and 100C may be configured so that the injection nozzles 100B and 100C respectively disposed in the left region 10b and the right region 10c may have different injection angle compared to the injection nozzle 100A disposed in the central region 10a. The plurality of injection nozzles 100A, 100B, and 100C may be disposed in inclined directions of the injection nozzles 100A, 100B, and 100C for each corresponding regions (10a, 10b, and 10c). For example, the injection nozzle 100A of the central region 10a may be disposed so that the first injection part 102 of the injection nozzle 100A is arranged in the second direction, the injection nozzle 100B of the left region 10b may be disposed so that the first injection part 102 of the injection nozzle 100B is arranged inclined toward left with respect to the second direction, and the injection nozzle 100C of the right region 10c may be disposed so that the first injection part 102 of the injection nozzle 100C may be arranged inclined toward right with respect to the second direction. As such, the arrangement of the injection nozzles 100A, 100B, and 100C coupled with the deposition source 10 may be changed to control a maximum radiation angle of the deposition source 10, so the radiation angle of the deposition material radiated from the deposition source 10 may be controlled and thereby the shadow phenomenon may be decreased or minimized.

An operation of the depositing apparatus according to the exemplary embodiments and a method for manufacturing a display device will be described with reference to the foregoing exemplary embodiments.

First, the substrate 20 may be disposed in the vacuum chamber, the deposition source 10 configured to radiate the deposition material 200 may be disposed facing the substrate 20, and one side of the deposition source 10 that is facing the substrate 20 may be coupled with the plurality of injection nozzles 100 through which the deposition material 200 is injected. The substrate 20 may be disposed by controlling the distance between the deposition source 10 and the substrate 20 so that the deposition material 200 may be incident at a predetermined inclined angle θ1. Next, the deposition material 200 is injected toward the substrate 20 through the injection nozzle 100 while the deposition source 10 is moved in a deposition moving direction.

When the deposition material 200 is deposited on the substrate 20, the inclined angle θ1 of the injection nozzle 100 with reference with the second direction which is the deposition direction may be set in consideration of the distance between the substrate 20 and the deposition source 10, the size of the substrate 20, the deposition quantity, and the like.

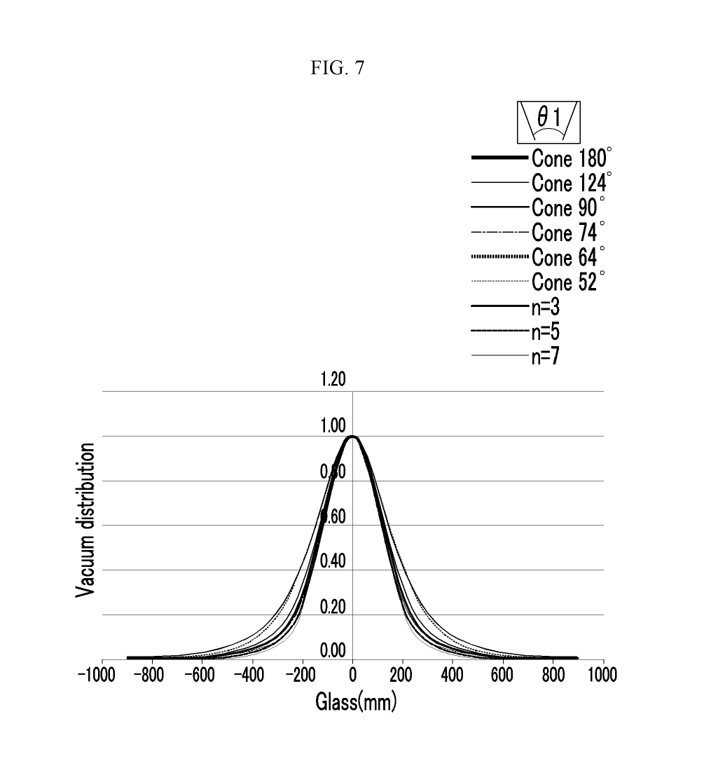

FIG. 7 is a graph illustrating a change in a film thickness according to an inclined angle θ1 of a second injection passage, according to the exemplary embodiments. Referring to FIG. 7, the inclined angle θ1 of the injection nozzle 100 may have a value in a range from 90° to 140°. More specifically, the inclined angle θ1 of the injection nozzle 100 may be 124°. When the inclined angle θ1 of the injection nozzle 100 is smaller than 90°, the deposition material 200 is permeated between the mask 30 and the substrate 20 and the shadow phenomenon may occur. Further, when the inclined angle θ1 of the injection nozzle 100 is larger than 140°, the incident quantity of deposition material 200 may be decreased and thus, the deposition efficiency may be reduced.

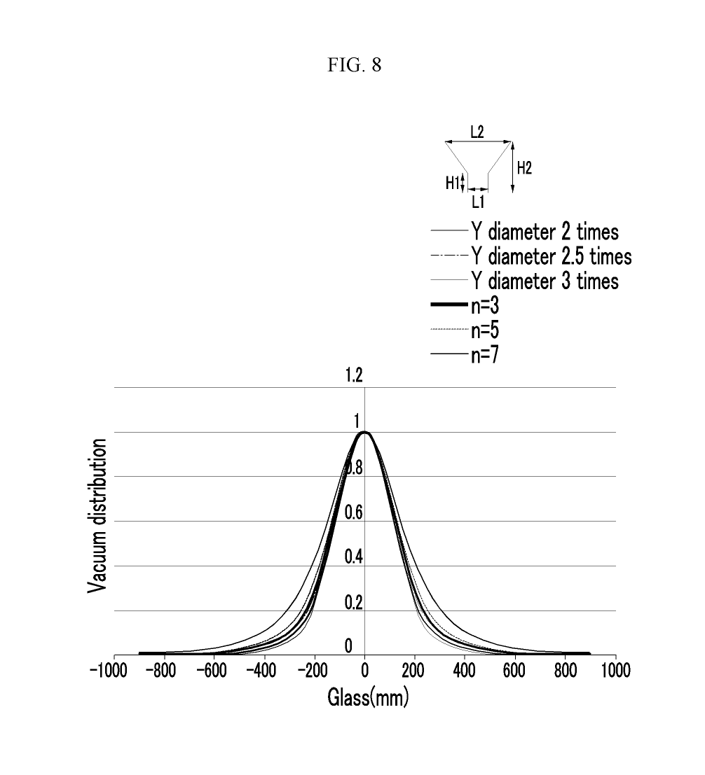

FIG. 8 is a graph illustrating the change in the film thickness depending on a length ratio of the injection nozzle, according to the exemplary embodiments. Referring to FIG. 8, a sharpness of the film thickness resolution may be controlled in response to the condition of the diameter L1 of the outlet of the first injection passage and the diameter L2 of the outlet of the second injection passage in a Y type injection nozzle. The diameter L2 of the outlet of the second injection passage may be formed to be greater than the diameter L1 of the outlet of the first injection passage. Referring to FIG. 8, the diameter L2 of the outlet of the second injection passage may be formed to be three times the diameter L1 of the outlet of the first injection passage.

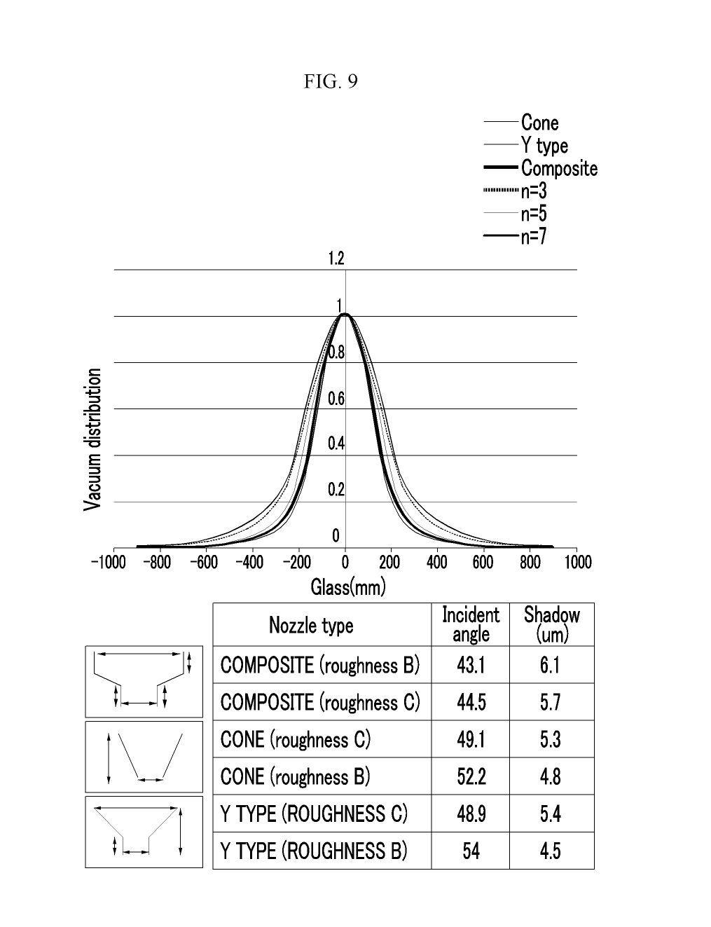

FIG. 9 is a graph illustrating the change in the film thickness depending on a shape of the injection nozzle, according to the exemplary embodiments. Referring to FIG. 9, the sharpness of the film thickness resolution may be controlled in response to various conditions of the injection nozzle. That is, a conical injection nozzle may have a sharpness of the film thickness resolution greater than that of a composite injection nozzle, and the Y type injection nozzle may have a sharpness of the film thickness resolution greater than that of the conical injection nozzle. Further, FIG. 9 shows different the shadow value according to the surface roughness conditions B (from 0.2 μm to 0.5 μm) and C (greater than 0.5 μm). Referring to FIG. 9, the Y type injection nozzle, depending on the surface roughness may generate the least amount of the shadow value.

According to the exemplary embodiments, the shadow phenomenon that the deposition material is permeated between the mask and the substrate and the deposition margin may be reduced. Furthermore, the resolution of the display device may be increased by increasing the deposition uniformity and the deposition efficiency.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A depositing apparatus, comprising:
a deposition source disposed facing a substrate and configured to accommodate a deposition material; and
a plurality of injection nozzles arranged from one side of the deposition source along a first direction, the plurality of injection nozzles configured to inject the deposition material onto the substrate, each injection nozzle comprising:
a first injection part comprising a first injection passage which has one end connected to the deposition source and extends along a second direction between the deposition source and the substrate, and
a second injection part comprising a second injection passage which has walls extending from the other end of the first injection passage in a direction inclined at a predetermined inclined angle with respect to the second direction,
wherein the first direction is a length direction of the deposition source and the second direction is a height direction of the deposition source.

2. The depositing apparatus of claim 1, wherein each of the plurality of injection nozzles meets the following condition:
(L1/H1)≧(L2/H2)
wherein L1 represents a diameter of an outlet of a first injection passage in the first direction, L2 represents a diameter of an outlet in a second injection passage in the first direction, H1 represents a length of the first injection passage in the second direction, and H2 represents a length of the second injection passage in the second direction

3. The depositing apparatus of claim 2, wherein the second direction is orthogonal to the first direction and the length of the second injection passage is longer than the length of the first injection passage.

4. The depositing apparatus of claim 3, wherein the first injection passage is formed in a straight tube shape along the second direction, and
wherein a diameter of an inlet of the first injection passage is the same as the diameter of the outlet of the first injection passage.

5. The depositing apparatus of claim 4, wherein a diameter of the outlet of the second injection passage is larger than the diameter of the outlet of the first injection passage.

6. The depositing apparatus of claim 5, wherein the second injection passage is formed with walls expanding out from the inlet of the second injection passage toward the outlet of the second injection passage.

7. The depositing apparatus of claim 5, wherein the second injection passage is formed with walls inclined outward at the outlet of the second injection passage.

8. The depositing apparatus of claim 5, wherein the diameter of the outlet of the second injection passage is three times as that of the outlet of the first injection passage.

9. The depositing apparatus of claim 1, wherein an angle between inclined walls of the second injection passage ranges from 90° to 140°.

10. The depositing apparatus of claim 1, wherein a surface roughness of an inner surface of the first injection passage is different from that of an inner surface of the second injection passage.

11. The depositing apparatus of claim 10, wherein the surface roughness of the inner surface of the first injection passage is greater than that of the inner surface of the second injection passage.

12. The depositing apparatus of claim 1, further comprising:
a nozzle protecting part coupled between the deposition source and the plurality of injection nozzles, the nozzle protecting part configured to protect the plurality of injection nozzles.

13. The depositing apparatus of claim 12, wherein the nozzle protecting part comprises:
a heater coupled around the first injection part, the heater configured to supply heat to the injection nozzle;
a nozzle cover disposed on the heater and coupled around a second injection part, the nozzle cover configured to protect the injection nozzle; and
a heat insulation coating layer disposed on a surface of the nozzle cover facing the substrate.

14. The depositing apparatus of claim 1, wherein the deposition source comprises:
a central region disposed in the center of the deposition source in the first direction; and
a left region and a right region disposed at each side of the central region, and
wherein the first injection part disposed in the central region extends in the second direction, the first injection part disposed in the left region extends inclined toward the left with respect to the second direction, and the first injection part disposed in the right region extends inclined toward right with respect to the second direction.
